(19) United States
(12) Patent Application Publication
(10) Pub. No.: US 2022/0382927 A1
(43) Pub. Date: Dec. 1, 2022

(54) COMPUTER-ASSISTED METHOD AND SYSTEM FOR DETERMINING AND VISUALISING FORCE FLOWS IN A SCAFFOLD

(71) Applicant: Peri SE, Weissenhorn (DE)

(72) Inventors: Wolfgang Span, Weissenhorn (DE); Henning Staves, Weissenhorn (DE)

(21) Appl. No.: 17/773,761

(22) PCT Filed: Oct. 23, 2020
(86) PCT No.: PCT/EP2020/079861

§ 371 Date: May 2, 2022

(30) Foreign Application Priority Data
Oct. 30, 2019 (DE) 10 2019 216 792.6

(51) Int. Cl. G06F 30/13; G06F 30/17

(52) U.S. Cl. CPC G06F 30/13; G06F 30/17

(57) ABSTRACT

The invention relates to a system and method for determining and visualizing force flows in a bar supporting structure (1), which is preferably in the form of scaffolding, comprising a plurality of ladder or strut elements (5a-5c) which extend vertically and are set up in a disputed manner relative to one another and which are detachably connected via scaffolding couplings (7) to strut elements (6a-6d) extending diagonally and/or horizontally transversely thereto, wherein at least a load-critical part of the support elements (5a-5c) and/or strut elements (6a-6d) and/or scaffold couplings (7) of the bar structure (1) are provided with load sensors (8a-8c) for detecting static operating load values, the measured values of which are analysed in real time by a downstream analysis unit (9) for evaluating current load situations.

### REFERENCE TO RELATED APPLICATIONS

This application claims priority to German Patent Application No. 10 2019 216 792.6, filed Oct. 30, 2019, which is incorporated herein by reference in its entirety.

The present invention relates to a system for determining and visualizing at least force flows, but optionally also moment progressions, in a bar supporting structure, which can be designed, for example, in the form of scaffolding and comprises a number of vertically running and spaced ladder or column elements, which are detachably connected via scaffolding couplings to strut elements running diagonally and/or horizontally thereto. In addition, the invention also relates to a computer-assisted method for planning the arrangement of load sensors in such a bar structure, and to a computer-assisted method for monitoring the operation of the bar structure with installed load sensors. Furthermore, the invention relates to computer programs in which the two aforementioned methods are embodied.

The field of application of the invention extends to the construction and monitoring of sensor-equipped bar supporting structures, which can be designed as an auxiliary structure in the form of scaffolding, for example working scaffolding, protective scaffolding or false work, and is generally used to make parts of buildings under construction or to be renovated, in LK: particular building facades, accessible to construction workers. In addition, the invention also extends to applications of bar supporting structures in the form of slab props, push-pull props and also to climbing structures or tunnel formwork.

### STATE OF THE ART

The general state of the art gives rise to the system scaffolds of interest here, which essentially consist of vertical ladder or column elements and brace elements running diagonally or horizontally transversely thereto, which are releasably held together by scaffold couplings. For example, rotary couplings or parallel couplings are used as scaffold couplings. The above-mentioned components are provided in accordance with a modular system and can be combined to form different scaffolds depending on the part of the building to be scaffolded.

In accordance with applicable regulations, such as those issued by the German Institute for Building Technology (DIBt), the designer and user of scaffolding is required to provide structural proof by means of corresponding generally known calculations of the member structure on which the scaffolding is based. However, in practice, an overload of a scaffold erected can occur, for example, when ultimate loads are exceeded or when connecting elements come loose in the area of nodes. Such events endanger safety on the construction site.

It is therefore the task of the present invention to create a system and a corresponding method as well as a computer program with which the current load situation of a scaffold can be monitored in a simple manner.

### DISCLOSURE OF THE INVENTION

The task is solved starting from a system according to the generic term of claim 1 in connection with its characterizing features. With regard to a computer-aided method for planning the arrangement of load sensors in a bar supporting structure representing a scaffold, reference is made to claim 13. Claim 15 discloses a computer-assisted method for monitoring the operation of the bar support structure via the load sensors installed therein. Claims 20 and 21 are directed to computer programs, each embodying one of the computer-assisted methods disclosed above.

The invention includes the technical teaching that at least one load-critical part of the column elements and/or strut elements and/or scaffold couplings of the bar structure, which can be identified according to empirical values, are equipped with load sensors for recording static operating load values, the measured values of which are evaluated in real time by a downstream analysis unit for identifying current load situations of the scaffold. The load sensors of the framework, which are networked in accordance with the invention, permit evaluation with regard to a wide range of different load situations.

The advantage of the solution according to the invention lies in particular in the fact that an intelligent scaffold is created which is accessible to a metrological load evaluation. Not all components of the scaffold need to be equipped with the load sensors of the invention, but only the load-critical part. The load-critical part of the scaffold is defined as those areas which, in terms of their arrangement and operating load, are subject to greater bending, buckling or similar deformations than the other areas of the scaffold. This load-critical part is determined on the basis of the structural design and can also be identified, for example, by a load simulation.

In addition to conventional scaffolding, the solution according to the invention can also be used in connection with other supporting structures, such as slab formwork, tunnel lining or bridge scaffolding, which are included here. With the aid of the load sensor system, damaging forces and moments become visible even before damage occurs, so that construction site safety is considerably improved as a result. In addition, an evaluation of the operating load of a scaffold can also determine whether all scaffold elements installed therein are absolutely necessary or whether partial scaffold dismantling can also be carried out to save materials, for example by dismantling individual support elements. This may be desirable, for example, in a later construction phase, when a scaffold is used only for light-duty work. Furthermore, the load sensor system of the invention can also be used for life cycle monitoring of scaffold elements.

Preferably, the load sensors of the type of interest here are designed as sensor elements for detecting normal forces, shear forces and/or bending moments of column or strut elements of the bar structure. These can be integrated directly into the column or strut elements and are thus protected against damage. For example, a plate sensor can be used as the sensor element for detecting normal forces. Strain gauges on struts or supports or directly on the plate sensor can also be used to record bending moments.

According to a preferred embodiment, the load sensor provided for detecting normal forces is arranged integrated in the associated support element in such a way that the load sensor is placed between a lower and an upper part or at one of the ends of the support element in order to absorb compressive and tensile forces acting on the support element. In other words, the load sensor is thus combined with the support element in a sandwich arrangement. In order to prevent buckling of the support element in this arrangement, for example, a central guide pin or the like can connect the two parts of the support element to one another in an axially movable manner. The load sensor provided for this arrangement can be designed as an add-on part in order to subsequently equip support elements with it.

In addition, it is also possible to integrate load sensors for the detection of bending moments in particular in scaffold couplings, since these usually embody the nodes of the underlying bar structure where maximum bending moments occur, which represent essential load information.

In accordance with a measure that further improves the invention, the analysis unit connected to such a load sensor system issues a warning message to a responsible person at the construction site via a suitable communication channel in the event of an overload Ü of the bar supporting structure during its operation determined by comparing the current load situation A with a predefined limit load situation G. The warning message is issued by the analysis unit.

If the analysis unit is arranged directly locally on the scaffold, this can be done in particular by acoustic signalling on site. If the analysis unit is arranged at a central location and connected to the local load sensor system via a communication channel based on radio data transmission, for example, the warning message can be transmitted to the construction site via bidirectional communication on a return channel in the event of an overload. This can also be done, for example, to a mobile terminal of a person responsible for the construction site.

According to a preferred embodiment, the central or local analysis unit can be connected to a graphical monitor unit for visualizing load ranges of different strengths of the bar supporting structure. The load ranges can result in the planning stage for the arrangement of load sensors, for example, from a load simulation and are made available during the operation of a scaffold by the permanent measured value evaluation.

The monitor unit for visualizing areas of different loads on the bar structure can also be part of a mobile terminal on site in order to be able to make an immediate assessment.

According to a measure further illustrating the invention, it is proposed that the mobile terminal is equipped with proximity detection means for locally reading the measured value of a single load sensor. Such close-range detection means can contain, for example, a QR code reader, RFID chip or the like for identifying the load sensor, and a corresponding QR code or RFID transponder is provided on the load sensor as an optical or electronic identification means. This can be used to record individual values of load data on site. The mobile terminal can also be set up to calculate a total of the individual values read in order to determine and output an overall load (distribution). As a result, concreting cycles, for example, can be recorded and easily stored for documentation purposes and transferred to the central storage unit for archiving.

Alternatively, however, it is also possible to design at least the analysis unit of the system of the invention as a component of a central server device which is connected to the local load sensors of the scaffolding on the construction site via at least one communication channel. In this configuration, therefore, a centrally provided computer capacity can be utilized. The central server facility also forms an optional prerequisite for storing learning data from current monitoring processes obtained from the analysis unit on an associated memory unit, which can be used, for example, to support future planning of sensor arrangements in the same or similar bar structures.

According to a further measure improving the invention, it is provided that the system further comprises a planning unit for planning the arrangement of load sensors in a beam structure, which processes the static planning data supplied to it on the input side. This makes it possible to plan the arrangement of load sensors in a scaffold in a simple manner using the method described below:

A computer-aided method for planning the arrangement of load sensors in a beam structure of the system described above includes the following steps:
Provision of a structural design of the bar supporting structure designed as scaffolding,
Identify load areas in the member structure that are at risk of overload,
Selection of load sensors suitable for load detection on column elements and/or strut elements and/or scaffold couplers in the identified load range,
Positioning of the selected load sensors in at least the load critical part of the bar structure.

In addition, the planning of the load sensors to be positioned appropriately for monitoring also includes subsequent connection planning of a suitable central or local analysis unit for measurement signal evaluation.

Once a scaffold planned in this way has been erected on the construction site, the desired operational monitoring with regard to overloading can then be carried out, which comprises the following essential steps:
Continuously recording of measurement data from the load sensors in the beam structure by the analysis unit,
Evaluating of the recorded measurement data with regard to overload situations of the bar truss during operation.

This is the prerequisite for issuing an optional warning message to the person responsible on the construction site for danger prevention if an overload situation occurs.

For extended load monitoring, the measurement data of the load sensors integrated in or arranged on the support elements can also be evaluated to determine the presence and/or movement of persons on the scaffold. This makes it possible, for example, to detect an imminent scaffold overload if the maximum permissible number of persons is exceeded. In addition, temporary load differences between support elements can also provide data on movements on the scaffold, for example to obtain information on the progress of construction work.

Furthermore, the measurement data can also be evaluated with regard to the presence of additional objects on the scaffold. These can be, for example, pallets, building materials or scaffolding material. Usually, these are loads that are stored immobile for a longer period of time and thus form an additional local static load. This local static load, like the moving (personal) loads, can also be displayed graphically in a clear manner on a mobile terminal on site or a central monitoring instance for monitoring purposes.

It is also conceivable that, as part of the load monitoring process, the measurement data from the load sensors integrated in or arranged on the support elements are evaluated to identify unacceptably positioned, in particular unacceptably tilted, support elements by means of a plausibility check. If, in a group of support elements that are expected to be equally loaded, one support element deviates by an unusually low load measurement value, this may indicate an inclined position.

Furthermore, by comparing the measurement data of neighboring support elements, it is also possible to determine the construction progress of an area load carried by these elements, for example when concreting an intermediate floor of a building in sections. This can be output on site in the form of so-called live data in order, for example, to detect unacceptably uneven load distributions at an early stage so that they can be corrected if necessary before a construction defect and/or scaffold overload occurs.

The computer-aided method for planning the arrangement of the load sensors can preferably be implemented by means of a corresponding computer program, the commands of which can preferably be executed on the aforementioned planning unit.

The method for monitoring the operation of the bar supporting structure with the load sensors can also be implemented as a computer program, which is preferably executed on the analysis unit indicated above, which is preferably part of a central server device.

### DETAIL DESCRIPTION OF THE DRAWING

Further measures improving the invention are shown in more detail below together with a description of a preferred embodiment of the invention with reference to the figures. It shows:

FIG. 1 a schematic perspective view of a scaffold for supporting formwork panels for concreting a building section,

FIG. 2 a perspective view of a part of the scaffold according to FIG. 1,

FIG. 3 a schematic representation of a system for determining and visualizing force flows in the beam structure representing the scaffold,

FIG. 4 a flow chart of a computer-aided method for planning the arrangement of load sensors in the beam structure, and

FIG. 5 a flow chart of the computer-aided process for monitoring the operation of the bar structure.

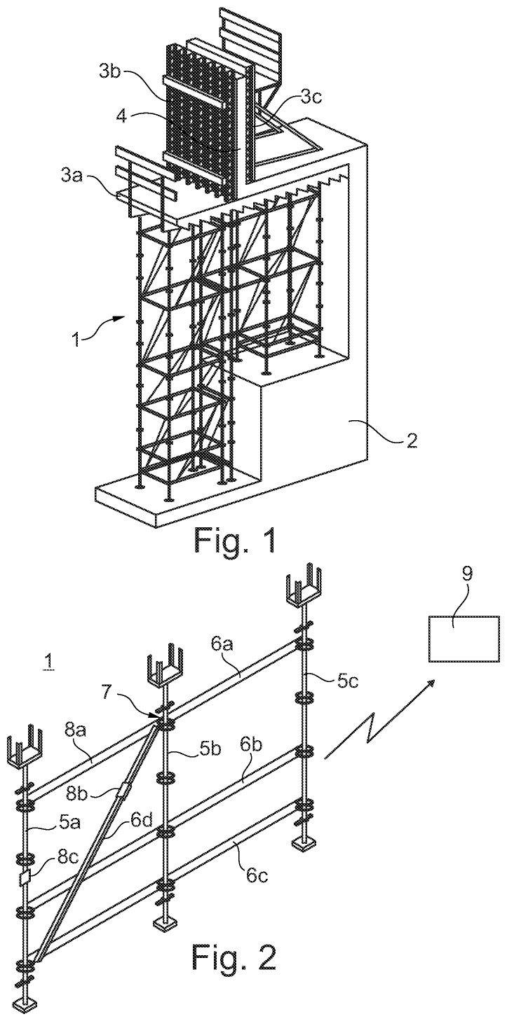

According to FIG. 1, a bar supporting structure 1 in the form of scaffolding is mounted on a building section 2. In this arrangement, the bar supporting structure 1 serves to support a formwork element 3a, which is combined with two further formwork elements 3b and 3c in order to concrete a wall section 4 of the building part 2.

FIG. 2 shows an exemplary part of the scaffold and thus of the beam structure 1. This comprises a total of three spaced-apart vertical support elements 5a to 5c, which are assembled with three horizontal strut elements 6a to 6c running transversely thereto and a strut element 6d running diagonally between the vertical support elements 5a and 5b for stabilization. The individual structural elements are detachably connected to one another by means of conventional scaffold couplings 7 (exemplary).

The depicted area of the bar framework 1 forms a load-critical part of the scaffold, which is provided with load sensors 8a to 8c (by way of example), each of which is arranged integrated in the scaffold elements. The individual load sensors 8a to 8c record the component stresses during use of the scaffold and forward them via an at least partially wireless communication channel to a remotely located central analysis unit 9 for evaluating current load situations of the scaffold.

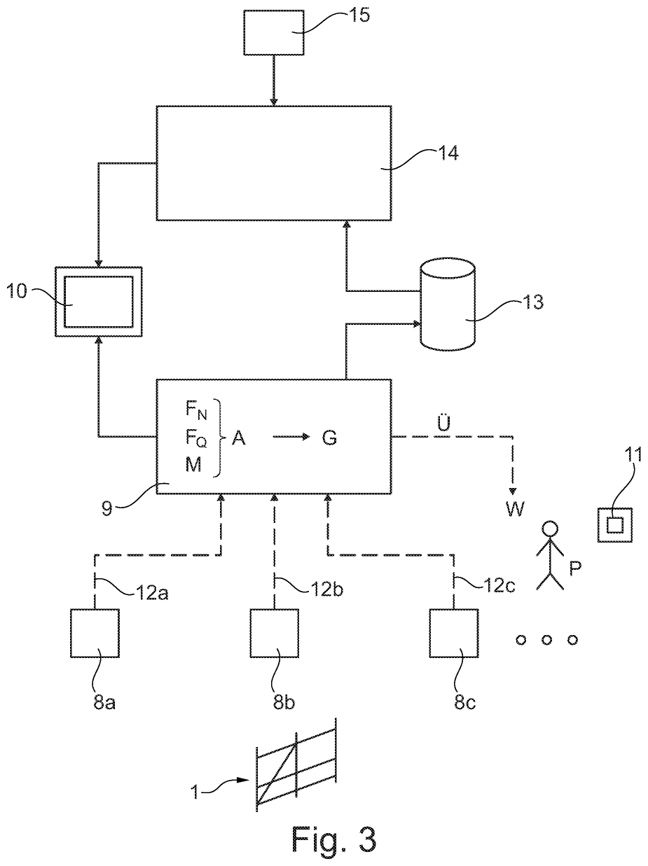

According to FIG. 3, the system illustrated here in the form of a block diagram for determining and visualizing force flows in the bar structure 1 comprises the several load sensors 8a to 8c of the bar structure 1 indicated above.

The analysis unit 9 uses the measured values to determine the normal forces F_{N}, the shear forces F_{Q} and the bending moments M_{B} in the bar structure 1, which represent the current load situation A of the scaffold. The current load situation A is compared with a predefined limit load situation G in order to determine an overload Ü of the bar structure 1 if the latter is exceeded. Such an overload Ü is then transmitted via a retransmission communication channel as a warning message W to a responsible person P at the construction site. This can be done, for example, by signaling on a mobile terminal 11 of the person in charge P via app or a messenger. This gives the person in charge P at the construction site the opportunity to react to the signaled overload Ü in an accident-preventing manner.

For monitoring purposes, the central analysis unit 9 is connected to a graphical monitor unit integrated in the app of the mobile terminal 11 of the person responsible P for visualizing load situations of the bar supporting structure 1. In addition, the current load situation can also be centrally monitored visually via a further monitor unit 11 arranged in the area of the central analysis unit 9.

As a central component of a server device, the analysis unit 9 is connected via sensor-specific communication channels 12a to 12c to the local load sensors 8a to 8c of the scaffolding representing the bar structure 1 on the construction site.

Furthermore, the analysis unit 9 is connected to a memory unit 13 for storing learning data for supporting future planning of sensor arrangements in the same or similar bar structures 1′.

For this purpose, a planning unit 14 is provided as a further component of the central server device. The planning unit 14 is provided for planning the arrangement of the load sensors 8a to 8c in the beam structure 1, which thus creates the prerequisite for the subsequent realization and monitoring. In this respect, the planning to be carried out with the planning unit 14 must take place before the load monitoring. In this context, the planning unit 14 is also connected to the graphic monitor unit 10 for visualization of the installation planning and uses the dimensioning data resulting from the static planning 15 of the bar structure 1 to carry out the planning task.

FIG. 4 illustrates the computer-aided method for planning the arrangement of load sensors 8a to 8c in a beam structure 1 of the system described above. The following steps are carried out, the reference signs referring to the system representation according to FIG. 3:

Initially, it is necessary to provide a structural design 15 of the framework 1 to be erected as scaffolding. This is then used as the basis for identifying b load areas in the framework 1 that are at risk of overload, for example by load simulation. Based on this in turn, a selection c of suitable load sensors 8a to 8c is carried out, which are suitable for load detection on the relevant scaffold parts in the identified load area at risk of overload. Finally, the selected load sensors 8a to 8c are arranged by positioning D in the load area of the bar truss 1 at risk of overload in order to be able to measure the current load situation therein. Finally, a determination e of the data connection to the analysis unit 9 is to be carried out within the scope of the planning, which can take place, for example, by radio data transmission, mobile radio, WLAN via directed connection channels or at least partial use of the Internet. In the case of an analysis unit 9 located locally on the construction site, this can also be done by conventional wire connection.

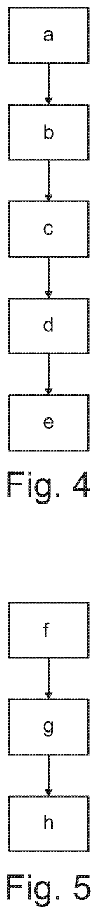

FIG. 5 shows the essential sequence of steps of a subsequent operational monitoring of the bar structure 1 with the load sensors 8a to 8c, in which a continuous recording f of measurement data of the load sensors 8a to 8c in the bar structure 1 is carried out by the analysis unit 9. Subsequently, an evaluation g of the recorded measurement data is performed with respect to the load situation of the bar supporting structure 1 during operation in the manner discussed above. If it is detected that an overload situation h has occurred, a warning message is issued to the person in charge at the construction site to avert danger.

Both the planning procedure described above for the load sensor arrangement in the beam structure and the subsequent real operation monitoring procedure of the scaffolding based on this can be executed in each case as software, which is run on the respective planning unit 14 designed as computer units or the analysis unit 9 of the central server device or elsewhere.

The invention is not limited to the preferred embodiment described above. On the contrary, variations thereof are also conceivable, which are also covered by the scope of protection of the following claims. For example, it is also possible to install the planning unit and/or analysis unit separately from each other and locally on the construction site. Likewise, load sensors can also be designed differently, provided that they are suitable in principle for detecting load situations on a scaffold, for example in the form of an optical sensor system.

List of reference signs

| | |
|---|---|
| 1 | Staff structure |
| 2 | Building section |
| 3 | Formwork elements |
| 4 | Wall section |
| 5 | Ladder or column elements |
| 6 | Strut elements |
| 7 | Scaffold coupling |
| 8 | Load sensor |
| 9 | Analysis unit |
| 10 | Monitor unit |
| 11 | Mobile terminal |
| 12 | Communication channel |
| 13 | Storage unit |
| 14 | Planning unit |
| 15 | Static planning |
| F_{N} | Normal force |
| F_{Q} | Shear force |
| M_{B} | Bending moment |
| A | current load situation |
| G | predefined limit load situation |
| Ü | determined overload |
| W | warning message |
| P | responsible person on site |

1. System for determining and visualizing force flows in a bar supporting structure (1), which is preferably designed in the form of a scaffold, comprising a plurality of ladder or strut elements (5a-5c) which run vertically and are set up in an objectionable manner with respect to one another and which are detachably connected via scaffold couplings (7) to strut elements (6a-6d) which run diagonally and/or horizontally transversely with respect thereto, characterized in that at least a load-critical part of the support elements (5a-5c) and/or strut elements (6a-6d) and/or scaffold couplings (7) of the bar supporting structure (1) are provided with load sensors (8a-8c) for detecting static operating load values, the measured values of which are analysed in real time by a downstream analysis unit (9) for evaluating current load situations.

2. System according to claim 1,
characterized in that the load sensors (8a-8c) are designed as sensor elements for detecting normal forces (F_{N}), transverse forces (F_{Q}) and/or bending moments (M_{B}) of column or strut elements (5a-5c; 6a-6d) in the beam structure (1).

3. System according to claim 2,
characterized in that the load sensor (8c) provided for detecting normal forces (F_{N}) is arranged integrated in the associated support element (5a; 5b; 5c) in such a way that the load sensor (8c) is placed between a lower and an upper part or at one of the ends of the support element (5a; 5b; 5c) in order to pick up compressive and tensile forces acting on the support element (5a; 5b; 5c).

4. System according to claim 2,
characterized in that load sensors (8a-8c) are arranged integrated in the support or strut elements (5a-5c; 6a-6d).

5. System according to claim 2,
characterized in that load sensors (8) for detecting bending moments (M_{B}) are integrated in scaffold couplings (7).

6. System according to claim 1,
characterized in that, in the event of an overload (Ü) of the bar supporting structure (1) determined by comparing the current load situation (A) with a predefined limit load situation (G), the analysis unit (9) outputs a warning message (W) to a responsible person (P) at the construction site via a communication channel.

7. System according to claim 1,
characterized in that the analysis unit (9) is connected to a graphic monitor unit (10) for the central visualization of load situations of the bar supporting structure (1).

8. System according to claim 1,
characterized in that the current load situation is monitored on site via a monitor unit of a mobile terminal (11) of the person in charge (P) arranged on the side of the construction site.

9. System according to claim 8,
characterized in that the mobile terminal (11) is equipped with close-range detection means for locally reading out the measured value of a single load sensor (8a; 8b; 8c) which is equipped with optical or electronic identification means for this purpose.

10. System according to claim 1,
characterized in that at least the analysis unit (9) is part of a central server device which is connected to the local load sensors (8a-8c) of the scaffold via at least one communication channel (12a-12c).

11. System according to claim 1,
characterized in that the analysis unit (9) is connected to a memory unit (13) for storing learning data for supporting future planning of sensor arrangements in the same or similar bar structures (1).

12. System according to claim 1,
characterized in that a planning unit (14) for planning the arrangement of load sensors (8a-8c) in a beam structure (1) is provided, which processes the dimensioning data of the static planning (15).

13. Computer-aided method for planning the arrangement of load sensors (8a-8c) in a beam structure (1) of a system according to any of the preceding claims, comprising the following steps:
Providing (a) a structural design (15) of the bar supporting structure (1) to be erected as scaffolding,
Identifying (b) load areas in the member structure (1) that are at risk of overload,
Selecting (c) of load sensors (8a-8c) suitable for load detection on column elements (5a-5c) and/or strut elements (6a-6d) and/or scaffold couplers (7) in the identified load range,
Positioning (d) of the selected load sensors (8a-8c) in the at least load-critical part of the bar structure (1).

14. Method according to claim 13,
characterized in that a determining (e) of the data connection of the load sensors (8a-8c) positioned in a manner suitable for monitoring to the analysis unit (9) to be connected thereto is carried out.

15. Computer-assisted method for operational monitoring of a rod support structure (1) with load sensors (8a-8c) of a system according to any of the preceding claims 1 to 12 with regard to an overload, comprising the following steps:
Continuous recording (f) of measurement data from the load sensors (8a-8c) in the beam structure (1) by the analysis unit (9),
Evaluating (g) of the recorded measurement data with regard to overload situations of the bar structure (1) during operation.

16. Method according to claim 15,
characterized in that, for extended load monitoring, the measurement data of the load sensors (8c) integrated in the support elements (5a-5c) or arranged thereon are evaluated in such a way that a presence and/or movement of persons located on the bar supporting structure (1) designed as scaffolding or a presence of additional objects there is determined.

17. Method according to claim 15,
characterized in that, for extended load monitoring, the measurement data of the load sensors (8c) integrated in the support elements (5a-5c) or arranged thereon are evaluated to the effect that impermissibly positioned, in particular impermissibly inclined, support elements (5a-5c) are identified by means of a plausibility check.

18. Method according to claim 15,
characterized in that the construction progress of a surface load carried by adjacent support elements (5a-5c) is determined by comparing the measurement data of load sensors (8c).

19. Method according to claim 11,
characterized in that when an overload situation (h) occurs, a warning message is issued to the person in charge (P) at the construction site to avert danger.

20. Computer program comprising instructions which, when the program is executed by a computer-aided planning unit (14), cause it to execute the method/steps of the method according to claim 13.

21. Computer program comprising instructions which, when the program is executed by a computer-aided analysis unit (9), cause the unit to execute the method/steps of the method according to claim 15.
